(19) United States
(12) Patent Application Publication
(10) Pub. No.: US 2024/0241185 A1
(43) Pub. Date: Jul. 18, 2024

(54) ESTIMATION METHOD FOR STATE OF HEALTH OF BATTERY

(71) Applicant: STL TECHNOLOGY CO., LTD., Kaohsiung City (TW)

(72) Inventors: Wen-Fan Chang, KAOHSIUNG CITY (TW); Chun-Chieh Li, KAOHSIUNG CITY (TW); Shih-Fa Hung, KAOHSIUNG CITY (TW); Jian-Min Chen, KAOHSIUNG CITY (TW)

(21) Appl. No.: 18/220,617

(22) Filed: Jul. 11, 2023

(30) Foreign Application Priority Data
Jan. 18, 2023 (TW) 112102423

(51) Int. Cl. G01R 31/392; G01R 31/389; H02J 7/00

(52) U.S. Cl. CPC G01R 31/392; G01R 31/389; H02J 7/005; H02J 7/007182

(57) ABSTRACT

This disclosure provides an estimation method applied to a state of health of a battery, which executes a recharging to a battery when a battery voltage is lower than a threshold voltage. During the recharging, a battery state of health estimation procedure is performed from a first depth of discharge detection point to a second depth of discharge detection point. During the battery state of health estimation procedure, a voltage difference between a current battery voltage and an initial open-circuit voltage is accumulated over time from the first depth of discharge detection point to the second depth of discharge detection point to obtain an accumulation of current sampled voltage difference. An accumulation of estimated DC internal resistances can be equivalently obtained by the accumulation of current sampled voltage difference. Afterwards, the state of health of the battery can be determined based on the accumulation of estimated DC internal resistance.

This non-provisional application claims priority claim under 35 U.S.C. § 119(a) on Taiwan Patent Application No. 112102423 filed Jan. 18, 2023, the entire contents of which are incorporated herein by reference.

### FIELD OF THE INVENTION

The present invention relates to an estimation method, in particular to a method for estimating a state of health of a battery in a regular recharging phase.

### BACKGROUND

The battery can be used for storing electrical energy. Multiple batteries are connected in series or parallel to become a battery module. When the battery module is used, it is necessary to estimate a state of health (SOH) of the battery within the battery module so as to know the SOH of the battery and therefore decide whether to replace the battery.

Previously, in order to estimate the SOH of the battery, it was necessary to enter a special mode by pressing a button so that the battery state of health estimation procedure can be activated. Alternatively, a special condition is set in the battery module, and when the special condition is met, the battery state of health estimation procedure will be activated. In the past, the battery state of health estimation procedure is usually performed by the means of discharging the battery. This not only affects the normal use of the battery module, but also results in the discharge of some energy for no reason.

In view of this above reason, the present disclosure provides an innovative estimation method for the SOH of the battery, in which the battery module can estimate the SOH of the battery during a regular recharging phase. So, in the estimation process of the SOH of the battery, it will not affect the energy storage operation of the battery module, and not need to discharge some energy for no reason, which will be the objective the present disclosure to be arrived.

### SUMMARY

It is one objective of the disclosure to provide an estimation method for a state of health of a battery, which establishes an initial open circuit voltage curve of the battery in advance and defines a depth of discharge sampling interval including a first detection point and a second detection point; when a current battery voltage of the battery is lower than a threshold voltage, a recharging of the battery will be executed; during the recharging, a battery state of health estimation procedure will be performed. In the battery state of health estimation procedure, it will measure a current battery voltage and a current discharge depth of the battery, and inquires an initial open circuit voltage corresponding to the current discharge of depth of the battery from the initial open circuit voltage curve; as the recharging progresses, a voltage difference between the current battery voltage corresponding to the current discharge of depth of the battery and the initial open circuit voltage corresponding to the current discharge of depth of the battery will be accumulated in sequential to obtain an accumulation of current sampled voltage differences; then, an accumulation of estimated DC internal resistances can be equivalently obtained by the accumulation of current sampled voltage difference. Afterwards, the state of health of the battery can be determined based on the accumulation of estimated DC internal resistances.

It is another objective of the disclosure to provide the estimation method for the state of health of the battery, which establishes an initial battery voltage curve of the battery in advance, inquires an initial open circuit voltage corresponding to each discharge of depth from the initial open circuit voltage curve, and inquires an initial battery voltage corresponding to each discharge of depth from the initial battery voltage curve; a voltage difference between the initial battery voltage corresponding to each depth of discharge and the initial open circuit voltage corresponding to each depth of discharge from the first detection point to the second detection point will be accumulated so as to obtain an accumulation of initial sampled voltage differences; an accumulation of initial DC internal resistances can be equivalently obtained by the accumulation of initial sampled voltage differences. Afterwards, the state of health of the battery can be determined based on a variation between the accumulation of estimated DC internal resistances and the accumulation of initial DC internal resistances.

It is another objective of the disclosure to provide the estimation method for the state of health of the battery, which further includes a battery aging estimation procedure. Before the battery aging estimation procedure performs, the battery state of health estimation procedure executes on a first reference battery that has used for a short time so as to obtain a first reference accumulation of DC internal resistances, the battery state of health estimation procedure executes on a second reference battery that has used for a long time so as to obtain a second reference accumulation of DC internal resistances, and a usage time of the first reference battery and a usage time of the second reference battery are obtained. In the battery aging estimation procedure, it will execute a battery life estimation formula, a first difference is obtained by subtracting the first reference accumulation of DC internal resistances from the accumulation of estimated DC internal resistances, a second difference is obtained by subtracting the first reference accumulation of DC internal resistances from the second reference accumulation of DC internal resistances, and an aging degree parameter of the battery is obtained by dividing the first difference by the second difference. A reference time difference is obtained by subtracting the usage time of the first reference battery from the usage time of the second reference battery. A usage time of the battery can be estimated by adding the usage time of the first reference battery to the product of the reference time difference and the aging degree parameter of the battery. When the second reference battery is an aging battery cell in poor health and close to being eliminated, a remaining service life of the battery can be obtained by subtracting the usage time of the battery from the usage time of the second reference battery.

To achieve the above objective, an estimation method applied to a state of health of a battery within a backup energy storage system, the backup energy storage system including a processor, the estimation method executed by the processor including: establishing an initial open circuit voltage curve of the battery in advance; defining a depth of discharge sampling interval including a first detection point and a second detection point, wherein a depth of discharge of the first detection point is greater than a depth of discharge of the second detection point; executing a recharging to the battery when a current battery voltage of the battery is lower than a threshold voltage; and executing a battery state of health estimation procedure by a battery state of health estimation program when a current discharge of depth of the battery is less than or equal to the depth of discharge of the first detection point; wherein the battery state of health estimation procedure including: inquiring an initial open circuit voltage corresponding to the current discharge of depth of the battery from the initial open circuit voltage curve; accumulating a voltage difference between the current battery voltage corresponding to the current discharge of depth of the battery and the initial open circuit voltage corresponding to the current discharge of depth of the battery in sequential as the recharging progresses; stopping to accumulate the voltage differences between the current battery voltage corresponding to the current discharge of depth of the battery and the initial open circuit voltage corresponding to the current discharge of depth of the battery so as to obtain an accumulation of current sampled voltage differences; obtaining an accumulation of estimated DC internal resistances equivalently by the accumulation of current sampled voltage differences; and determining the state of health of the battery based on the accumulation of estimated DC internal resistances.

In one embodiment of the present disclosure, the estimation method for the state of health of the battery further including: establishing an initial battery voltage curve of the battery in advance; inquiring an initial open circuit voltage corresponding to each discharge of depth from the initial open circuit voltage curve; inquiring an initial battery voltage corresponding to each discharge of depth from the initial battery voltage curve; accumulating a voltage difference between the initial battery voltage corresponding to each depth of discharge and the initial open circuit voltage corresponding to each depth of discharge from the first detection point to the second detection point so as to obtain an accumulation of initial sampled voltage differences; obtaining an accumulation of initial DC internal resistances equivalently by the accumulation of initial sampled voltage differences; and determining the state of health of the battery based on a variation between the accumulation of estimated DC internal resistances and the accumulation of initial DC internal resistances.

In one embodiment of the present disclosure, the estimation method for the state of health of the battery further including: executing the battery state of health estimation procedure on a first reference battery that has used for a short time so as to obtain a first reference accumulation of DC internal resistances; executing the battery state of health estimation procedure on a second reference battery that has used for a long time so as to obtain a second reference accumulation of DC internal resistances; obtaining a first difference by subtracting the first reference accumulation of DC internal resistances from the accumulation of estimated DC internal resistances; obtaining a second difference by subtracting the first reference accumulation of DC internal resistances from the second reference accumulation of DC internal resistances; and obtaining an aging degree parameter of the battery by dividing the first difference by the second difference.

In one embodiment of the present disclosure, the estimation method for the state of health of the battery further including: obtaining a usage time of the first reference battery; obtaining a usage time of the second reference battery; obtaining a reference time difference by subtracting the usage time of the first reference battery from the usage time of the second reference battery; and obtaining a usage time of the battery by adding the usage time of the first reference battery to the product of the reference time difference and the aging degree parameter of the battery.

In one embodiment of the present disclosure, wherein the second reference battery is an aging battery cell in poor health and close to being eliminated, the estimation method further including: obtaining a remaining service life of the battery by subtracting the usage time of the battery from the usage time of the second reference battery.

In one embodiment of the present disclosure, steps of establishing the initial open circuit voltage curve of the battery in advance including: charging the battery to its full capacity; discharging the battery by a small and constant discharge current; periodically measuring a current open circuit voltage of the battery in discharging; obtaining the current discharge of depth of the battery based on a current discharge capacity of the battery; recording the current open circuit voltage of the battery and the current depth of discharge of the battery that are corresponding to a current discharge time; determining whether the current open circuit voltage is equal to a discharge cut-off voltage; continuing the discharging of the battery and recording an open circuit voltage of the battery and a depth of discharge of the battery that are corresponding to the next discharge time if the current open circuit voltage of the battery is greater than the discharge cut-off voltage; and stopping to the discharging of the battery and establishing the initial open circuit voltage curve based on each open circuit voltage and each depth of discharge that are corresponding to each discharge time if the current open circuit voltage of the battery is equal to the discharge cut-off voltage.

In one embodiment of the present disclosure, steps of establishing the initial battery voltage curve of the battery in advance including: charging the battery for the first time; periodically measuring a current battery voltage and a charge current in charging; obtaining the current battery voltage and the current discharge of depth of the battery based on a current charge capacity of the battery; recording the current battery voltage and the current depth of discharge of the battery that are corresponding to a current charge time; determining whether the current battery voltage is equal to a fully charged voltage; continuing the charging of the battery and recording a battery voltage and a depth of discharge of the battery that are corresponding to the next charge time if the current battery voltage of the battery is not equal to the fully charged voltage; and stopping to the charging of the battery and establishing the initial battery voltage curve based on each battery voltage and each depth of discharge that are corresponding to each charge time if the current battery voltage of the battery is equal to the fully charged voltage.

In one embodiment of the present disclosure, wherein the battery state of health estimation program includes a flag; when the flag is set to 1, the battery state of health estimation program starts to perform the battery state of health estimation procedure; when the flag is set to 0, the battery state of health estimation program will be prohibited to perform the battery state of health estimation procedure.

In one embodiment of the present disclosure, the flag is set to 0 when the battery is discharging.

In one embodiment of the present disclosure, the flag is set to 1 when the battery is recharged and the current depth of discharge of the battery is smaller than or equal to the depth of discharge of the first detection point.

### BRIEF DESCRIPTION OF THE DRAWINGS

FIG. 1 is a circuit block diagram of a battery module of the present disclosure.

FIG. 2 is a schematic diagram of the variation of battery voltage during the use of the battery module of the present disclosure.

FIG. 3 is a circuit diagram of a battery charged by a charger of the present disclosure.

FIG. 4 is a flowchart of measuring an open circuit voltage curve of the present disclose.

FIG. 5 is a flowchart of measuring a battery voltage curve of the present disclose.

FIG. 6 is a view including an initial open circuit voltage curve, an initial battery voltage curve, a current open circuit voltage curve, and a current battery voltage curve of the battery of the present disclosure.

FIG. 7 is a timed task flowchart of the battery module of the present disclosure.

FIG. 8 is a flowchart of estimating a state of health of the battery of the present disclosure.

FIG. 9 is a flowchart of estimating the aging degree of the battery of the present disclosure.

### DETAILED DESCRIPTION OF THE PREFERRED EMBODIMENTS

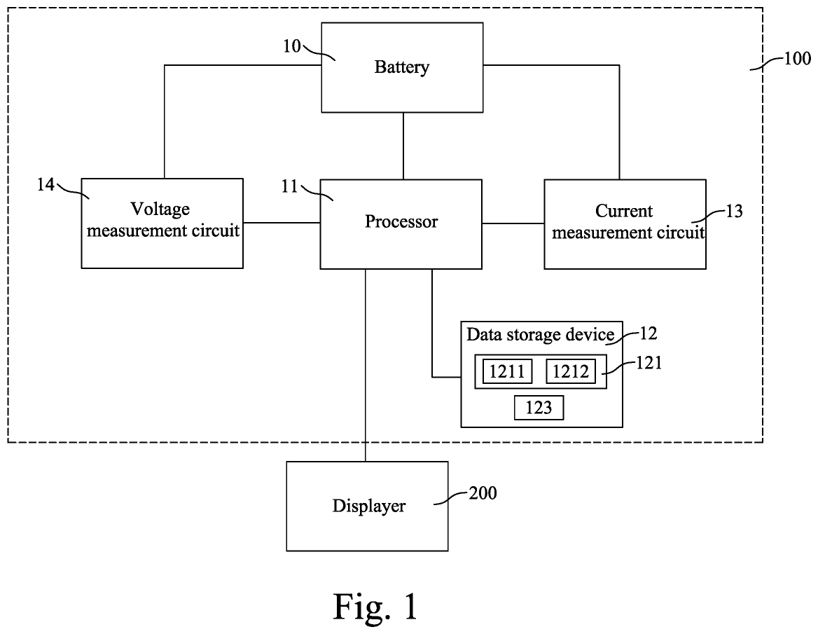

Referring to FIGS. 1, 2, and 3, there are shown a circuit block diagram of a battery module of the present disclosure, a schematic diagram of the variation of battery voltage during the use of the battery module of the present disclosure, and a circuit diagram of a battery charged by a charger of the present disclosure. The battery module of the present disclosure is applied to a backup energy storage system, for example, uninterruptible power supply (UPS) or energy storage system (ESS), and used as a power supply source of the backup power. As shown in FIG. 1, the battery module 100 includes at least one battery 10, a processor 11, a data storage device 12, a current measurement circuit 13, and a voltage measurement circuit 14. The processor 11 is connected to the battery 10, the data storage device 12, the current measurement circuit 13, and the voltage measuring circuit 14. The data storage device 12 is a non-volatile memory, such as a flash memory, which is used to store a battery state of health (SOH) estimation program 121. The processor 11 can estimate the SOH of the battery 10 by the battery SOH estimation program 121.

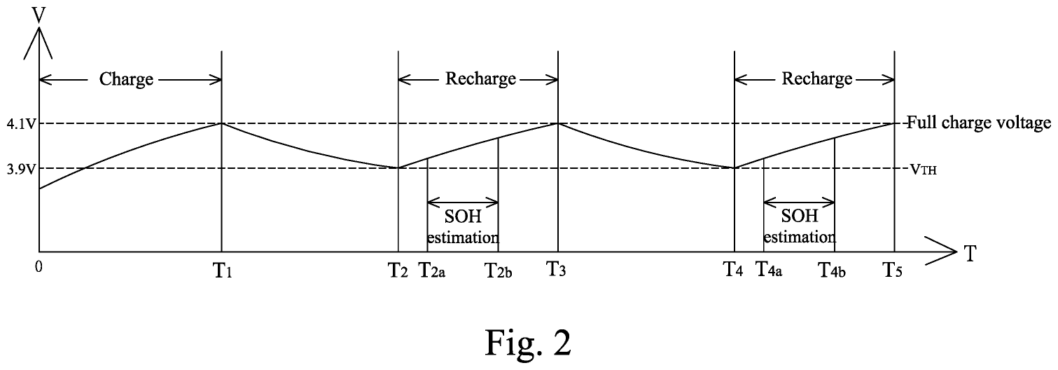

In order to ensure the safety of battery modules (such as lithium-ion battery modules) during transportation, according to transportation regulations, the State of Charge (SOC) of the 100 battery module 100 must be kept below 30% during transportation. When the battery module 100 is assembled in the energy storage system and used for the first time, the battery 10 must be charged to a fully charged state, such as state of charge (SOC) is 100%, so that a battery voltage (V_{BAT}) of the battery module 100 can be charged to a full charged voltage (such as 4.1V), as shown in FIG. 2. In the present disclosure, although 4.1V is used as an example for full charged voltage, in actual situations, the full charged voltage will be adjusted according to different battery models. Besides, when the battery module 100 is used as a backup power source, it is necessary to keep the battery 10 of the module in a fully charged state and ensure that its battery voltage (V_{BAT}) remains at a higher level so as to provide sufficient energy to be drawn by the power storage system. Afterwards, when the energy of the battery 10 is not drawn for a period of time, the battery voltage (V_{BAT}) of the battery 10 will still drop because of the factors of self-discharging. As shown in FIG. 1 and FIG. 2, the processor 11 measures the battery voltage (V_{BAT}) of the battery 10 by voltage measurement circuit 14. When the processor 11 measures that the battery voltage (V_{BAT}) of the battery 10 is lower than a threshold voltage (V_{H}), for example, 3.9V, it will execute a recharging to the battery 10 so that the battery voltage (V_{BAT}) can resume the voltage level of the fully charged state. In the present disclosure, during the execution of the recharging, the battery module 100 of the present disclosure will execute a battery SOH estimation procedure at the same time. As shown in FIG. 2, the battery SOH estimation procedure can be executed between time ranges of T₂ₐ-T_{2b} during the recharge phase T₂-T₃ or executed between time ranges of T₄ₐ-T_{4b} during the recharge phase T₄-T₅. Thus, the battery module 100 of the present disclosure can estimates the SOH of the battery 10 without the need for entering a special mode or discharging.

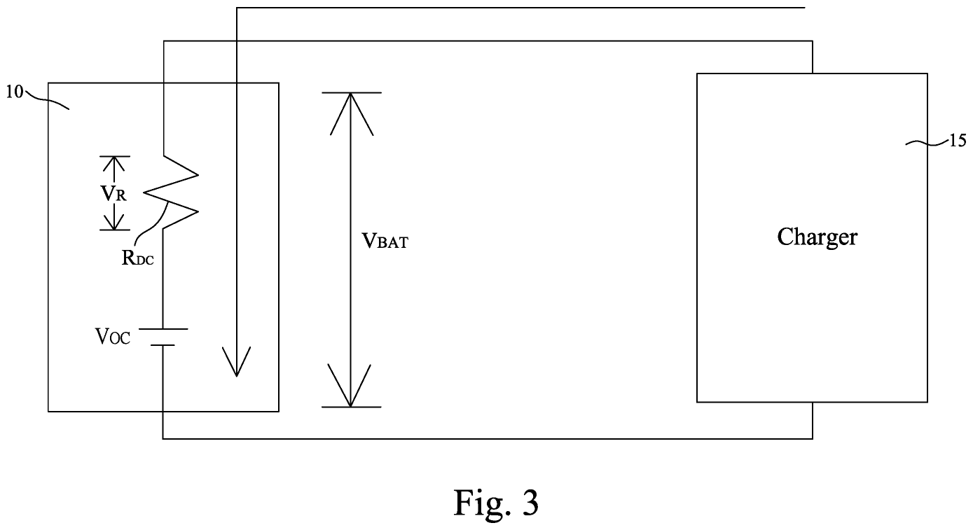

Further referring to FIG. 1 and FIG. 3, the battery module 100 can execute a charging to the battery 10 by a charger 15. The charger 15 may be a component placed in the inside of the battery module 100, or may be an external device relative to the battery module 100. When the battery module 100 is operating in a charging mode, a connection between the battery 10 and the charger 15 can be conducted by the controlling of the processor 11, so that the charger 15 can execute the charging to the battery 10. Besides, the battery 10 includes a DC internal resistance (R_{DC}). The DC internal resistance (R_{DC}) varies with the different capacities of the battery 10, and generates an internal resistance voltage (V_{R}) thereon. The battery voltage (V_{BAT}) of the battery 10 is equal to a sum of the internal resistance voltage (V_{R}) and an open circuit voltage (V_{OC}), for example, V_{BAT}=V_{R}+V_{OC}.

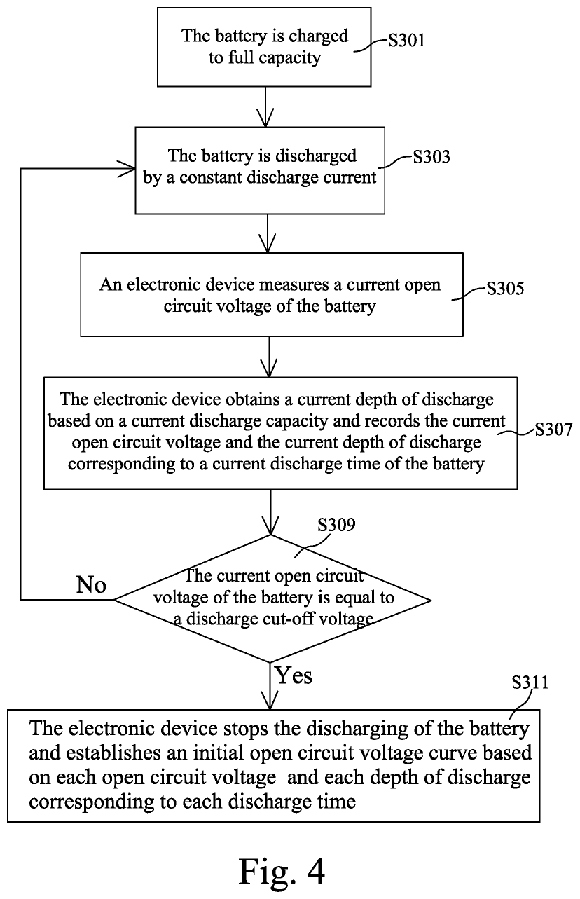

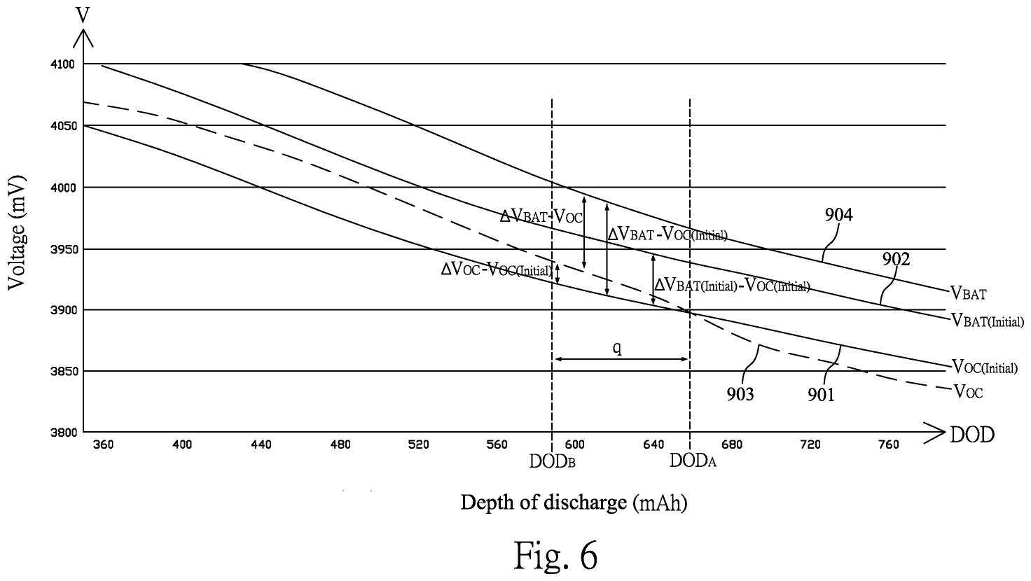

When the battery module 100 is initially used, for example, when the battery module 100 is initially assembled into the energy storage system, a measurement procedure of an initial open circuit voltage curve is performed on the battery 10 in advance. As shown in FIG. 4, in the measurement procedure of the initial open circuit voltage curve, firstly, in step S301, the battery 10 is charged to full capacity under a standard charging condition. Then, in step S303, the battery 10 can be discharged by a small and constant discharge current (such as I_{D}=0.1 mA). In step S305, an electronic device (such as working computer) periodically measures a current open circuit voltage (V_{OC}) of the battery 10 in discharging by a voltage and current measurement device. In step S307, the electronic device obtains a current depth of discharge (DOD) based on a current discharge capacity (I_{D}×T_{D}). For example, T_{D} represents a current discharge time, where the current depth of discharge (DOD) is equal to a previous depth of discharge (DOD_{PREV}) plus the current discharge capacity (I_{D}×T_{D}), DOD=DOD_{PREV}+(I_{D}×T_{D}). The electronic device records the current open circuit voltage (V_{OC}) and the current depth of discharge (DOD) corresponding to the current discharge time (T_{D}) of the battery 10. Then, in step S309, the electronic device determines whether the current open circuit voltage (V_{OC}) is equal to a discharge cut-off voltage. If the current open circuit voltage (V_{OC}) of the battery 10 is not equal to the discharge cut-off voltage, returning to steps S303, S305, and S307, the electronic device continues to record the open circuit voltage (V_{OC}) and the depth of discharge (DOD) corresponding to the next discharge time (T_{D}). On the contrary, if the current open circuit voltage (V_{OC}) of the battery 10 is equal to the discharge cut-off voltage, step S311 is performed, the electronic device stops the discharging of the battery 10, and establishes an initial open circuit voltage curve 901 based on each open circuit voltage (V_{OC}) corresponding to each discharge time (T_{D}) and each depth of discharge (DOD) corresponding to each discharge time (T_{D}), as shown in FIG. 6. In one embodiment of the present disclosure, the electronic device stores the initial open circuit voltage curve 901 in the data storage device 12.

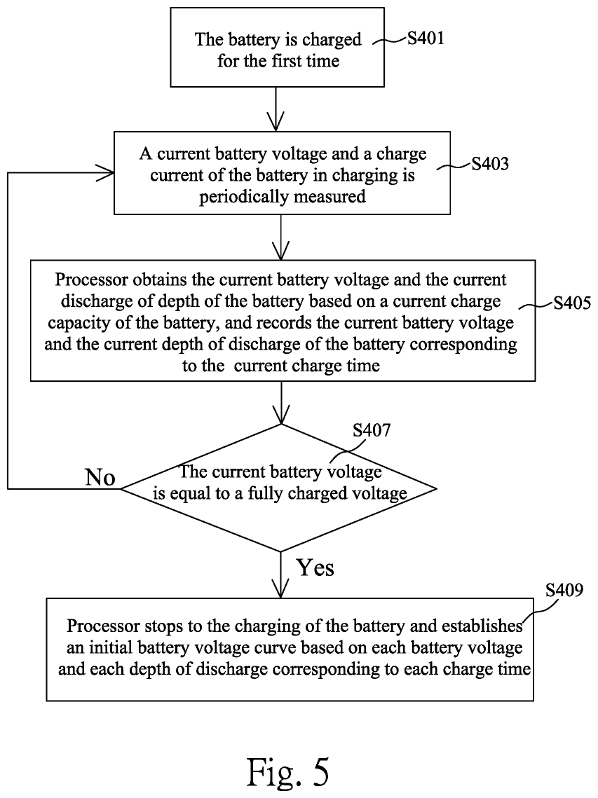

When the battery module 100 is initially used, for example, when the battery module 100 is charged for the first time, a measurement procedure of an initial battery voltage curve will be performed. As shown in FIG. 5, in the measurement procedure of the initial battery voltage curve, firstly, in step S401, when the battery module 100 is initially used, the processor 11 charges the battery 10 for the first time by the charger 15. In step S403, the processor 11 periodically measures a current battery voltage (V_{BAT}) and a charging current (I_{C}). The charging current (I_{C}) is a constant current. In step S405, the processor 11 obtains a current depth of discharge (DOD) based on a current charge capacity (I_{C}×T_{C}). For example, T_{C} represents a current charge time, where the current depth of discharge (DOD) is equal to a previous depth of discharge (DOD_{PREV}) minus the current charge capacity (I_{C}×T_{C}), DOD=DOD_{PREV}−(I_{C}×T_{C}). The processor 11 records the current battery voltage (V_{BAT}), the current depth of discharge (DOD) and the charging current (I_{C}) that are corresponding to the current charge time (T_{C}). Then, in step S407, the processor 11 determines whether the current battery voltage (V_{BAT}) is equal to a fully charged voltage. If the current battery voltage (V_{BAT}) of the battery 10 is not equal to the fully charged voltage, returning to steps S403 and S405, the processor 11 continues to record the battery voltage (V_{BAT}) and the depth of discharge (DOD) that are corresponding to the next charge time (T_{C}). On the contrary, if the current battery voltage (V_{BAT}) of the battery 10 is equal to the fully charged voltage, step S409 is performed, the processor 11 stops the charging of the battery 10, and establishes an initial battery voltage curve 902 based on each battery voltage (V_{BAT}) and each depth of discharge (DOD) corresponding to each charge time (T_{C}), as shown in FIG. 6. In one embodiment of the disclosure, the processor 11 stores the initial battery voltage curve 902 in the data storage device 12.

Furthermore, as shown in FIG. 1 and FIG. 6, the battery SOH estimation program 121 defines a depth of discharge sampling interval 1211. The depth of discharge sampling interval 1211 includes a first detection point (DOD_{A}) and a second detection point (DOD_{B}). The depth of discharge of the first detection point (DOD_{A}) is greater than that of the second detection point (DOD_{B}). For example, the depth of discharge of the first detection point (DOD_{A}) is designed as 660 mAh, and the depth of discharge of the second detection point (DOD_{B}) is designed as 590 mAh. In the above description, the detection points defined in the depth of discharge sampling interval 1211 by the processor 11 are only an example. In the fact, the range of the depth of discharge sampling interval 1211 and its detection points can be appropriately adjusted based on the accuracy required for estimating the SOH of the battery 10.

The battery SOH estimation program 121 further includes a flag 1212. When the flag 1212 is set to 1, the processor 11 starts to perform a battery SOH estimation procedure. When the flag 1212 is set to 0, the processor 11 will be prohibited to perform the battery SOH estimation procedure.

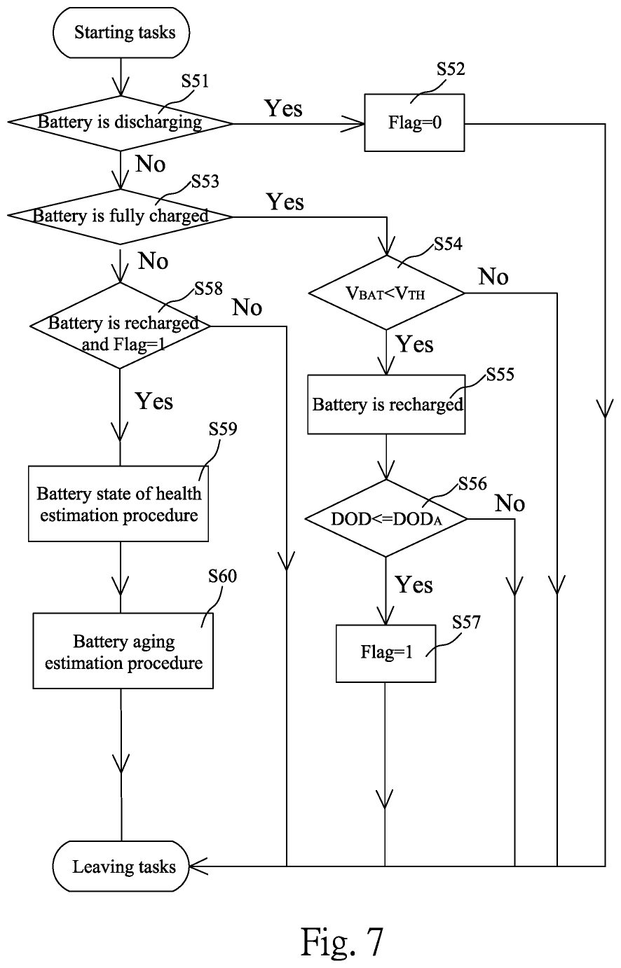

Referring to FIGS. 7, 8, and 9, there are shown a timed task flowchart of the battery module of the present disclosure, a flowchart of estimating a state of health of the battery of the present disclosure, and a flowchart of estimating the aging degree of the battery of the present disclosure. As shown in FIG. 7, the processor 11 of the battery module 100 periodically performs tasks by the battery SOH estimation program 121. Firstly, in step S51, the processor 11 detects whether the battery 10 is discharging. If the battery 10 is discharging, performing step S52, the processor 11 sets the flag 1212 to 0 and leaves the tasks. If the battery 10 is not discharged, performing step S53, the processor 11 detects whether the battery 10 is fully charged by the voltage measurement circuit 14. If the battery 10 is fully charged, performing step S54, the processor 11 detects whether the battery voltage (V_{BAT}) is lower than the threshold voltage (V_{TH}). If the battery voltage (V_{BAT}) is higher than the threshold voltage (V_{TH}), the processor 11 leaves the tasks. On the contrary, if the battery voltage (V_{BAT}) is lower than the threshold voltage (V_{TH}), performing step S55, the processor 11 recharges the battery 10 by the charger 15. Then, performing step S56, the processor 11 periodically measures whether the current depth of discharge (DOD) of the battery 10 is equal to or less than the depth of discharge of the first detection point (DOD_{A}). If the current depth of discharge (DOD) of the battery 10 is higher than the depth of discharge of the first detection point (DOD_{A}), the processor 11 leaves the tasks. On the contrary, if the current depth of discharge (DOD) of the battery 10 is equal to or less than the depth of discharge of the first detection point (DOD_{A}), performing step S57, the processor 11 sets the flag 1212 to 1, and then leaves the tasks.

Returning to steps S51 and step S53, if the battery 10 is neither discharged nor fully charged, performing step S58, the processor 11 determines whether the battery 10 is recharged and checks if the flag 1212 is set to 1. If the battery 10 is not recharged or the flag 1212 is set to 0, the processor 11 leaves the tasks. On the contrary, if the battery 10 is recharging and the flag 1212 is set to 1, the processor 11 enters a battery SOH estimation procedure S59.

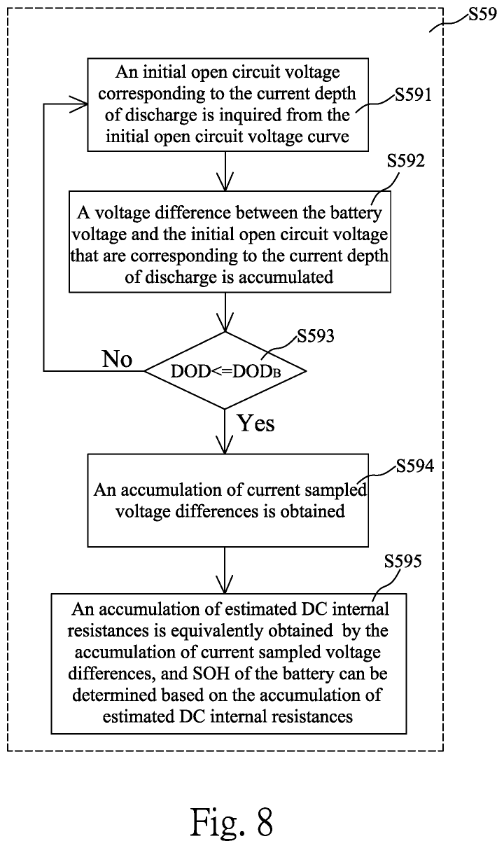

As shown in FIG. 8, in the battery SOH estimation procedure S59, firstly, performing step S591, the processor 11 inquiries an initial open circuit voltage (V_{OC(Initial)}) corresponding to the current depth of discharge (DOD) from the initial open circuit voltage curve 901. In step S592, with the progress of recharging, the processor 11 sequentially accumulates a voltage difference (V_{BAT}−V_{OC(Initial)}) between the battery voltage (V_{BAT}) and the initial open circuit voltage (V_{OC(Initial)}) that are corresponding to the current depth of discharge (DOD). In step S593, with the progress of recharging, the processor 11 determines whether the current depth of discharge (DOD) of the battery 10 is less than or equal to the depth of discharge of the second detection point (DOD_{B}). If the current depth of discharge (DOD) of the battery 10 is not less than or not equal to the depth of discharge of the second detection point (DOD_{B}), returning to steps S591 and S592, the processor 11 continues to accumulate the voltage differences (V_{BAT}−V_{OC(Initial)}). On the contrary, if the current depth of discharge (DOD) of the battery 10 is less than or equal to the depth of discharge of the second detection point (DOD_{B}), performing to step S594, the processor 11 stops to accumulate the voltage differences (V_{BAT}−V_{OC(Initial)}), and therefore obtains an accumulation (∫ₐ^{b}V_{BAT}−V_{OC(Initial)}) of current sampled voltage differences. In step S595, the processor 11 obtains an accumulation (∫_{A}^{B}R_{DC(EST)}dq=∫ₐ^{b}V_{BAT}−V_{OC(Initial)}) of estimated DC internal resistances equivalently by the accumulation of current sampled voltage differences (∫ₐ^{b}V_{BAT}−V_{OC(Initial)}). For example, at the same time, the variation in the voltage difference between the battery voltage (V_{BAT}) and the open circuit voltage (Voc) is equivalent to the variation in the DC internal resistance (R_{DC}) with respect to the battery capacity; therefore, the voltage differences (V_{BAT}−V_{OC(Initial)}) between the battery voltage (V_{BAT}) and the initial open circuit voltage (V_{OC(Initial)}) sampled from the first detection point (DOD_{A}) to the second detection point (DOD_{B}) can be equivalently regarded as the accumulation (∫_{A}^{B}R_{DC(EST)}dq) of estimated DC internal resistances from the first detection point (DOD_{A}) to the second detection point (DOD_{B}). In one embodiment of the present disclosure, the processor 11 includes an integrator. The processor 11 can calculate the accumulation of the voltage differences or the accumulation of the DC internal resistances by the integrator.

Furthermore, in addition to present the initial open circuit voltage curve 901 and the initial battery voltage curve 902, FIG. 6 further shows a current open circuit voltage curve 903 and a current battery voltage curve 904. The initial open circuit voltage curve 901 and the initial battery voltage curve 902 can be established in advance when the battery module 100 is initially used. The processor 11 can generate the current battery voltage curve 904 by measuring the current battery voltage (V_{BAT}) by the voltage measurement circuit 14 during the recharging or discharging of the battery 10. Furthermore, the current open circuit voltage (V_{OC}) is unable to be measured during the recharging or discharging of the battery 10, and it will vary at any time according to the aging degree of the battery 10. As a result, the current open circuit voltage curve 903 cannot be accurately obtained. Here, for the convenience of subsequent technical explanations, the current open circuit voltage curve 903 will be represented on FIG. 6 in a type of hypothetical.

Taking FIG. 6 as an example, based on the current battery voltage curve 904 and the current open circuit voltage curve 903, the processor 11 obtains an accumulation (∫ₐ^{b}V_{BAT}−V_{OC}) of voltage differences (V_{BAT}−V_{OC}) between the current battery voltage and the current open circuit voltage from the first detection point (DOD_{A}) to the second detection point (DOD_{B}), and therefore obtains an accumulation (∫_{A}^{B}R_{DC}dq=∫ₐ^{b}V_{BAT}−V_{OC}) of current DC internal resistances (R_{DC}) equivalently by the accumulation (V_{BAT}−V_{OC}) of voltage differences (V_{BAT}−V_{OC}); based on the current open circuit voltage curve 903 and the initial open circuit voltage curve 901, the processor 11 obtains an accumulation (∫ₐ^{b}V_{OC}−V_{OC(Initial)}) of voltage differences (V_{OC}−V_{OC(Initial)}) between the current battery voltage and the initial open circuit voltage from the first detection point (DOD_{A}) to the second detection point (DOD_{B}), and therefore obtains an accumulation (∫_{A}^{B}R_{DC(Offset)}dq=∫ₐ^{b}V_{OC}−V_{OC(Initial)}) of offset DC internal resistances (R_{DC(offset)}) equivalently by the accumulation (∫ₐ^{b}V_{OC}−V_{OC(Initial)}) of voltage differences (V_{OC}−V_{OC(Initial)}).

Ideally, it is most accurate to determine the SOH of the battery 10 by the accumulation (∫_{A}^{B}R_{DC}dq) of current DC internal resistances (R_{DC}). However, as described above, since the current open circuit voltage (V_{OC}) is unable to be not measured during the charging or discharging of the battery 10, the accumulation (∫ₐ^{b}V_{BAT}−V_{OC}) of the voltage different (V_{BAT}−V_{OC}) cannot be obtained, and the accumulation (∫_{A}^{B}R_{DC}dq) of current DC internal resistances (R_{DC}) that is equivalently by the accumulation (∫ₐ^{b}V_{BAT}−V_{OC}) of the voltage different (V_{BAT}−V_{OC}) cannot be also obtained. Similarly, the accumulation (∫_{A}^{B}R_{DC(Offset)}dq) of offset DC internal resistances (R_{DC(offset)} that is equivalently by the accumulation (∫ₐ^{b}V_{OC}−V_{OC(Initial)}) of voltage differences (V_{OC}−V_{OC(Initial)}) cannot be also actually obtained.

Referring to FIG. 6, an accumulation of current sampled voltage differences is (∫ₐ^{b}V_{BAT}−V_{OC(Initial)}=∫ₐ^{b}V_{BAT}−V_{OC}+∫ₐ^{b}V_{OC}−V_{OC(Initial)}), and therefore the accumulation (∫_{A}^{B}R_{DC(EST)}dq) of estimated DC internal resistances is the sum of the accumulation (∫_{A}^{B}R_{DC}dq) of current DC internal resistances and the accumulation (∫_{A}^{B}R_{DC(Offset)}dq) of offset DC internal resistances, for example, ∫_{A}^{B}R_{DC(EST)}dq=∫_{A}^{B}R_{DC}dq+∫_{A}^{B}R_{DC(Offset)}dq. Accordingly, the battery module 100 of the present disclosure can determine the SOH of the battery 10 by the accumulation (∫_{A}^{B}R_{DC(EST)}dq) of estimated DC internal resistances.

Besides, when the battery module 100 is initially used, the processor 11 further inquiries the initial open circuit voltage (V_{OC(Initial)}) corresponding to each current depth of discharge (DOD) from the initial open circuit voltage curve 901, and further inquiries the initial battery voltage (V_{BAT(Initial)}) corresponding to each current depth of discharge (DOD) from the initial battery voltage curve 902. From the first detection point (DOD_{A}) to the second detection point (DOD_{B}), the processor 11 accumulates a voltage difference (V_{BAT(Initial)}−V_{OC(Initial)}) between the initial battery voltage (V_{BAT(Initial)}) corresponding to each depth of discharge (DOD) and the initial open circuit voltage (V_{OC(Initial)}) corresponding to each depth of discharge (DOD) so as to obtain an accumulation (∫ₐ^{b}V_{BAT(Initial)}−V_{OC(Initial)}) of initial voltage differences, and then obtains an accumulation (∫_{A}^{B}R_{DC(initinal)}dq=∫ₐ^{b}V_{BAT(Initial)}−V_{OC(Initial)}) of initial DC internal resistances equivalently by the accumulation of initial voltage differences (∫ₐ^{b}V_{BAT(Initial)}−V_{OC(Initial)}).

In one embodiment of the present disclosure, the processor 11 determines the SOH of the battery 10 according to a variation between the accumulation (∫_{A}^{B}R_{DC(EST)}dq) of estimated DC internal resistances and the accumulation (∫_{A}^{B}R_{DC(initinal)}dq) of initial DC internal resistances. The variation between the accumulation (∫_{A}^{B}R_{DC(EST)}dq) of estimated DC internal resistances and the accumulation (∫_{A}^{B}R_{DC(initinal)}dq) of initial DC internal resistances is small, which represents that the aging degree of the battery 10 is not severe, and the SOH of the battery 10 is maintained at a better energy storage quality; on the contrary, the variation between the accumulation (∫_{A}^{B}R_{DC(EST)}dq) of estimated DC internal resistances and the accumulation (∫_{A}^{B}R_{DC(initinal)}dq) of initial DC internal resistances is large, which indicates that the aging degree of the battery 10 is severe, and the SOH of the battery 10 has declined to a poorer energy storage quality.

In another embodiment of the present disclosure, the processor 11 defines an upper threshold. When the variation between the accumulation (∫_{A}^{B}R_{DC(EST)}dq) of estimated DC internal resistances and the accumulation (∫_{A}^{B}R_{DC(initinal)}dq) of initial DC internal resistances is higher than the upper threshold, it represents that the SOH of the battery 10 is extremely poor. For example, the current storage capacity of the battery 10 may only be 60% of the original storage capacity. Besides, when the variation between the accumulation (∫_{A}^{B}R_{DC(EST)}dq) of estimated DC internal resistances and the accumulation (∫_{A}^{B}R_{DC(initinal)}dq) of initial DC internal resistances is higher than the upper threshold, the processor 11 issues a warning signal to remind the user of the battery module 100 that the current SOH of the battery 10 is extremely poor, and the battery 10 must be replaced as soon as possible. In one embodiment of the present disclosure, the battery module 100 is further connected to a displayer 200. The warning signal issued by the processor 11 can be appeared on the displayer 200 in the form of a text or a color mark.

Returning to the estimation procedure S59 in FIG. 7 and FIG. 8, after determining the SOH of the battery 10, the processor 11 ends the battery SOH estimation procedure S59 and leaves the tasks.

In another embodiment of the present disclosure, a battery aging estimation procedure S60 will continue to be performed after the battery SOH estimation procedure S59 has finished. Before the battery aging estimation procedure S60 performs, the data storage device 12 stores a first reference accumulation (∫_{A}^{B}R_{DC(New)}dq) of DC internal resistances and a second reference accumulation (∫_{A}^{B}R_{DC(Old)}dq) of DC internal resistances in advance. The first reference accumulation (∫_{A}^{B}R_{DC(New)}dq) of DC internal resistances is obtained by executing the battery SOH estimation procedure S59 on a first reference battery (such as new battery) that has used for a short time (such as charging less times). The second reference accumulation (∫_{A}^{B}R_{DC(Old)}dq) of DC internal resistances is obtained by executing the battery SOH estimation procedure S59 on a second reference battery (such as old battery) that has used for a long time (such as charging more times).

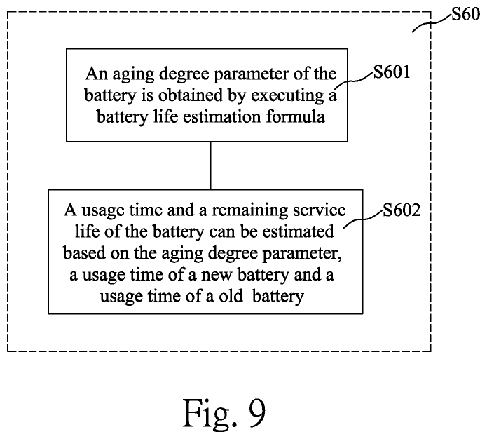

As shown in FIG. 9, in the battery aging estimation procedure S60, firstly, in step S601, when a battery life estimation formula 123 is executed by the processor 11, a first difference (∫_{A}^{B}R_{DC(EST)}dq−∫_{A}^{B}R_{DC(New)}dq) is obtained by subtracting the first reference accumulation (∫_{A}^{B}R_{DC(New)}dq) of DC internal resistances from the accumulation (∫_{A}^{B}R_{DC(EST)}dq) of estimated DC internal resistances, a second difference (∫_{A}^{B}R_{DC(Old)}dq−∫_{A}^{B}R_{DC(New)}dq) is obtained by subtracting the first reference accumulation (∫_{A}^{B}R_{DC(New)}dq) of DC internal resistances from the second reference accumulation (∫_{A}^{B}R_{DC(Old)}dq) of DC internal resistances, and an aging degree parameter (AGE_{DCR}=(∫_{A}^{B}R_{DC(EST)}dq−∫_{A}^{B}R_{DC(New)}dq)/(∫_{A}^{B}R_{DC(Old)}dq−∫_{A}^{B}R_{DC(New)}dq)) of the battery 10 is obtained by dividing the first difference by the second difference.

For example, the accumulation (∫_{A}^{B}R_{DC(EST)}dq) of estimated DC internal resistances is 300 mΩ, the first reference accumulation (∫_{A}^{B}R_{DC(New)}dq) of DC internal resistances is 100 mΩ, and the second reference accumulation (∫_{A}^{B}R_{DC(Old)}dq) is 900 mΩ, the aging degree parameter (AGE_{DCR}=(300 mΩ−100 mΩ)/(900 mΩ−100 mΩ)=0.25) can be obtained by executing the battery life estimation formula 123. If the aging degree parameter (AGE_{DCR}) is presented in percentage, it is 25%.

In step S602, the usage time (T_{A}) and remaining service life (T_{B}) of the battery 10 can be estimated based on the aging degree parameter (AGE_{DCR}), the usage time (T₁) of the first reference battery and the usage time (T₂) of the second reference battery. Assume that the first reference battery has been used in the energy storage system for 2 years, and the second reference battery has been used in the energy storage system for 12 years. Based on the aging degree parameter (AGE_{DCR}), the usage time (T₁) of the first reference battery, and the usage time (T₂) of the second reference battery, the usage time (T_{A}) of the battery 10 can be estimated to be about 4.5 years, for example, T_{A}=(T₂−T₁)×AGE_{DCR}+T₁=(12 years−2 years)×0.25+2 years=4.5 years. Furthermore, if the second reference battery is an aging battery cell in poor health and close to being eliminated, the remaining service life (T_{B}) of the battery 10 can be estimated to be about 7.5 years, for example, T_{B}=12 years-4.5 years=7.5 years. Thus, the usage time (T_{A}) and remaining service life (T_{B}) of the battery 10 can be estimated by executing the battery aging estimation procedure S60.

The above disclosure is only the preferred embodiment of the present invention, and not used for limiting the scope of the present invention. All equivalent variations and modifications on the basis of shapes, structures, features and spirits described in claims of the present invention should be included in the claims of the present invention.

1. An estimation method applied to a state of health of a battery within a backup energy storage system, the backup energy storage system including a processor, the estimation method executed by the processor including:
establishing an initial open circuit voltage curve of the battery in advance;
defining a depth of discharge sampling interval including a first detection point and a second detection point, wherein a depth of discharge of the first detection point is greater than a depth of discharge of the second detection point;
executing a recharging to the battery when a current battery voltage of the battery is lower than a threshold voltage; and
executing a battery state of health estimation procedure by a battery state of health estimation program when a current discharge of depth of the battery is less than or equal to the depth of discharge of the first detection point;
wherein the battery state of health estimation procedure including:
inquiring an initial open circuit voltage corresponding to the current discharge of depth of the battery from the initial open circuit voltage curve;
accumulating a voltage difference between the current battery voltage corresponding to the current discharge of depth of the battery and the initial open circuit voltage corresponding to the current discharge of depth of the battery in sequential as the recharging progresses;
stopping to accumulate the voltage differences between the current battery voltage corresponding to the current discharge of depth of the battery and the initial open circuit voltage corresponding to the current discharge of depth of the battery so as to obtain an accumulation of current sampled voltage differences;
obtaining an accumulation of estimated DC internal resistances equivalently by the accumulation of current sampled voltage differences; and
determining the state of health of the battery based on the accumulation of estimated DC internal resistances.

2. The estimation method according to claim 1, further including:
establishing an initial battery voltage curve of the battery in advance;
inquiring an initial open circuit voltage corresponding to each discharge of depth from the initial open circuit voltage curve;
inquiring an initial battery voltage corresponding to each discharge of depth from the initial battery voltage curve;
accumulating a voltage difference between the initial battery voltage corresponding to each depth of discharge and the initial open circuit voltage corresponding to each depth of discharge from the first detection point to the second detection point so as to obtain an accumulation of initial sampled voltage differences;
obtaining an accumulation of initial DC internal resistances equivalently by the accumulation of initial sampled voltage differences; and
determining the state of health of the battery based on a variation between the accumulation of estimated DC internal resistances and the accumulation of initial DC internal resistances.

3. The estimation method according to claim 1, further including:
executing the battery state of health estimation procedure on a first reference battery that has used for a short time so as to obtain a first reference accumulation of DC internal resistances;
executing the battery state of health estimation procedure on a second reference battery that has used for a long time so as to obtain a second reference accumulation of DC internal resistances;
obtaining a first difference by subtracting the first reference accumulation of DC internal resistances from the accumulation of estimated DC internal resistances;
obtaining a second difference by subtracting the first reference accumulation of DC internal resistances from the second reference accumulation of DC internal resistances; and
obtaining an aging degree parameter of the battery by dividing the first difference by the second difference.

4. The estimation method according to claim 3, further including:
obtaining a usage time of the first reference battery;
obtaining a usage time of the second reference battery;
obtaining a reference time difference by subtracting the usage time of the first reference battery from the usage time of the second reference battery; and
obtaining a usage time of the battery by adding the usage time of the first reference battery to the product of the reference time difference and the aging degree parameter of the battery.

5. The estimation method according to claim 4, wherein the second reference battery is an aging battery cell in poor health and close to being eliminated, the estimation method further including:
obtaining a remaining service life of the battery by subtracting the usage time of the battery from the usage time of the second reference battery.

6. The estimation method according to claim 1, steps of establishing the initial open circuit voltage curve of the battery in advance including:
charging the battery to its full capacity;
discharging the battery by a small and constant discharge current;
periodically measuring a current open circuit voltage of the battery in discharging;
obtaining the current discharge of depth of the battery based on a current discharge capacity of the battery;
recording the current open circuit voltage of the battery and the current depth of discharge of the battery that are corresponding to a current discharge time;
determining whether the current open circuit voltage is equal to a discharge cut-off voltage;
continuing the discharging of the battery and recording an open circuit voltage of the battery and a depth of discharge of the battery that are corresponding to the next discharge time if the current open circuit voltage of the battery is greater than the discharge cut-off voltage; and
stopping to the discharging of the battery and establishing the initial open circuit voltage curve based on each open circuit voltage and each depth of discharge that are corresponding to each discharge time if the current open circuit voltage of the battery is equal to the discharge cut-off voltage.

7. The estimation method according to claim 2, steps of establishing the initial battery voltage curve of the battery in advance including:
charging the battery for the first time;
periodically measuring a current battery voltage and a charge current in charging;
obtaining the current battery voltage and the current discharge of depth of the battery based on a current charge capacity of the battery;
recording the current battery voltage and the current depth of discharge of the battery that are corresponding to a current charge time;
determining whether the current battery voltage is equal to a fully charged voltage;
continuing the charging of the battery and recording a battery voltage and a depth of discharge of the battery that are corresponding to the next charge time if the current battery voltage of the battery is not equal to the fully charged voltage; and
stopping to the charging of the battery and establishing the initial battery voltage curve based on each battery voltage and each depth of discharge that are corresponding to each charge time if the current battery voltage of the battery is equal to the fully charged voltage.

8. The estimation method according to claim 1, wherein the battery state of health estimation program includes a flag; when the flag is set to 1, the battery state of health estimation program starts to perform the battery state of health estimation procedure; when the flag is set to 0, the battery state of health estimation program will be prohibited to perform the battery state of health estimation procedure.

9. The estimation method according to claim 8, further including:
setting the flag to 0 when the battery is discharging.

10. The estimation method according to claim 8, further including:
setting the flag to 1 when the battery is recharged and the current depth of discharge of the battery is smaller than or equal to the depth of discharge of the first detection point.
